(19) United States
(12) Patent Application Publication
(10) Pub. No.: US 2026/0159213 A1
(43) Pub. Date: Jun. 11, 2026

(54) MARINE VESSEL HEATING/COOLING SYSTEM

(71) Applicant: STEWART & STEVENSON LLC, Houston, TX (US)

(72) Inventors: Brian SHARP, Houston, TX (US); Jason ROBISON, Houston, TX (US); Vince TO, Houston, TX (US)

(21) Appl. No.: 19/397,099

(22) Filed: Nov. 21, 2025

Related U.S. Application Data
(60) Provisional application No. 63/729,811, filed on Dec. 9, 2024.

(51) Int. Cl. B63J 2/12; H05K 7/20

(52) U.S. Cl. CPC B63J 2/12; H05K 7/20272; H05K 7/20927; H05K 7/20945

(57) ABSTRACT

A marine vessel includes an electronics system positioned within the hull and a heating/cooling system. The heating/cooling system is positioned within the hull and the heating/cooling system includes a first heat transfer fluid. The heating cooling system may also include a pump and a supply manifold, the supply manifold in fluid connection with the pump and the electronics system. The heating/cooling system may also include a return manifold, the return manifold in fluid connection with the electronics system and a cooler, the cooler in fluid connection with the return manifold and the pump. The cooler may include a second heat transfer fluid. The system also includes a keel cooler, the keel cooler in fluid connection with the cooler. The keel cooler may also include seawater and the second heat transfer fluid.

### CROSS-REFERENCE TO RELATED APPLICATIONS

This application is a nonprovisional application which claims priority from U.S. provisional application No. 63/729,811, filed Dec. 9, 2024, which is incorporated by reference herein in its entirety.

### TECHNICAL FIELD/FIELD OF THE DISCLOSURE

The present disclosure relates generally to a cooling system for electronics on a marine vessel.

### BACKGROUND OF THE DISCLOSURE

Marine vessels often use cooling systems for removing heat in power systems. Traditional power systems have electronics that generate heat. Available coolants for marine vessels may include salt water, but salt water is corrosive and conductive, making leaks in traditional cooling systems damaging to equipment and direct cooling of electronics infeasible.

### SUMMARY

The present disclosure provides for a marine vessel. The marine vessel includes an electronics system positioned within the hull and a heating/cooling system. The heating/cooling system is positioned within the hull and the heating/cooling system includes a first heat transfer fluid. The heating cooling system may also include a pump and a supply manifold, the supply manifold in fluid connection with the pump and the electronics system. The heating/cooling system may also include a return manifold, the return manifold in fluid connection with electronics system and a cooler, the cooler in fluid connection with the return manifold and the pump. The cooler may include a second heat transfer fluid. The marine vessel also includes a keel cooler, the keel cooler in fluid connection with the cooler. The keel cooler may also include seawater and the second heat transfer fluid.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1 is schematic diagram of a marine vessel consistent with certain embodiments of the present disclosure.

FIG. 2 is a schematic diagram of a cooling system in connection with electronics aboard an ocean-going vessel consistent with certain embodiments of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

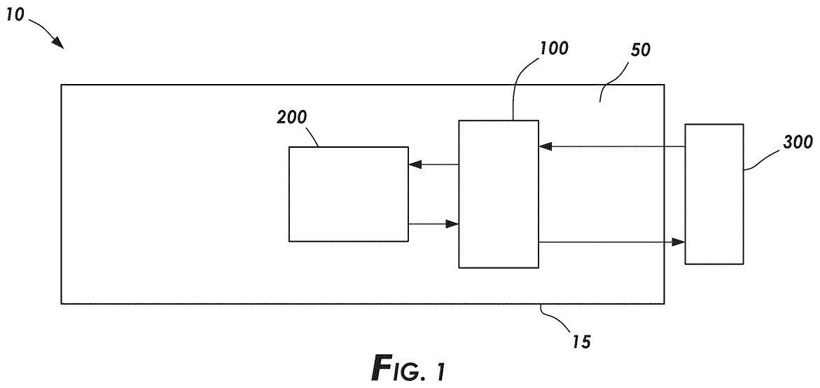

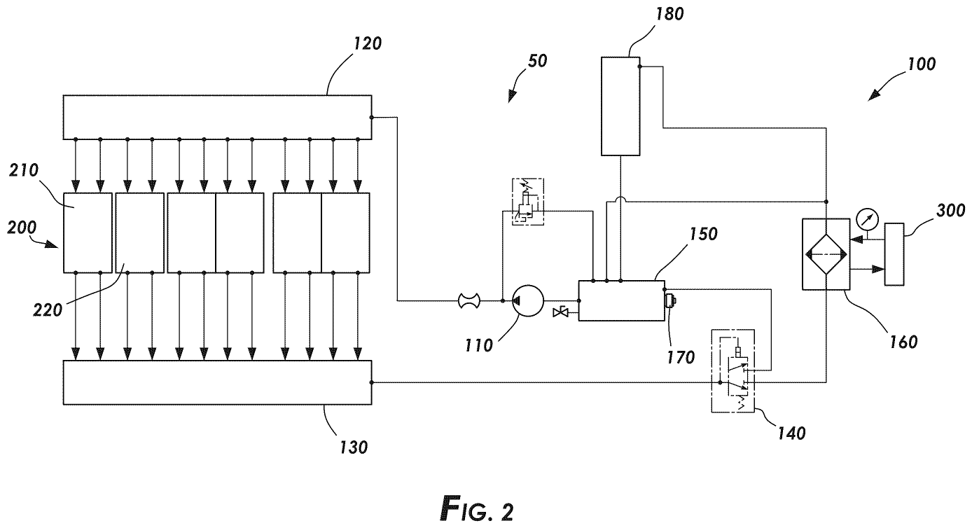

FIG. 1 depicts marine vessel 10. Marine vessel 10 may be, for example, a tug boat, barge, or ship. Marine vessel 10 may include hull 15, electronics system 200 and temperature adjustment system 50. Electronics system 200 may be positioned within hull 15. Further, electronics system 200 may include, for example and as shown in FIG. 2, variable frequency drives (VFDs) 210 and DC/DC converters 220 for use with equipment on board marine vessel 10.

Temperature adjustment system 50 may include heating/cooling system 100 and keel cooler 300. Heating/cooling system 100 may be positioned within hull 15. Heating/cooling system 100 may be tested for integrity prior to placing on marine vessel 10 separate from any testing of keel cooler 300. Heating/cooling system 100 may include pump 110. Pump 110 may provide motive power to a first heat transfer fluid that circulates within heating/cooling system 100. The first heat transfer fluid may be, for example and without limitation, a non-reactive and non-conductive fluid. Non-reactive may mean that first heat transfer fluid does not react with electronic equipment and the other elements of heating/cooling system 100. In non-limiting examples, the first heat transfer fluid may be an ethylene glycol and water mixture, a propylene glycol and water mixture, or a dielectric fluid perfluorinated carbon. In some embodiments, heating/cooling system 100 may provide cooling for cooling of variable frequency drive (VFD) 210 and DC/DC converter 220. In some embodiments, marine vessel 10 may include two heating/cooling systems 100 in case of failure of one heating/cooling system 100. Further, two heating/cooling systems 100 may allow marine vessel 10 to operate on a single motor. In certain embodiments, heating/cooling system 100 may be a closed system, i.e., that no additional make up streams or other streams may feed heating/cooling system 100.

Pump 110 may be in fluid connection with supply manifold 120. Supply manifold 120 may distribute the first heat transfer fluid to VFDs 210 and DC/DC converters 220 within electronics system 200 to heat or cool the VFDs 210 and DC/DC converters 220. After the first heat transfer fluid flows through VFDs 210 and DC/DC converters 220, the first heat transfer fluid flows to return manifold 130. The first heat transfer fluid then flows through thermostat 140. Thermostat 140 routes flow of the first heat transfer fluid to either pump supply manifold 150 if the temperature measured by thermostat 140 is below or at a predetermined temperature or through cooler 160 if above the predetermined temperature. In certain embodiments, cooler 160 may be a plate and frame heat exchanger. In some embodiments, heater 170 may be attached to pump supply manifold 150. Heater 170 may be activated when first heat transfer fluid temperature at thermostat 140 is below the predetermined temperature. In certain embodiments, by heating first heat transfer fluid to a predetermined temperature, condensation of water within VFDs 210 may be prevented.

The first heat transfer fluid in cooler 160 may exchange heat with a second heat transfer fluid from keel cooler 300. Keel cooler 300 allows the second heat transfer fluid to circulate through a system of tubing outside hull 15 of marine vessel 10 using the lower temperature of seawater outside marine vessel 10 to reduce the second heat transfer fluid temperature via heat exchange. In certain non-limiting examples, keel cooler 300 may be in the form of a tank within the hull adjacent to the vessel's hull. In other embodiments, keel cooler 300 may include baffles to increase heat transfer.

While keel cooler 300 is fluidly connected to cooler 160, keel cooler 300 is not part of heating/cooling system 100 and the second heat transfer fluid and the first heat transfer fluid do not intermix. By separating the sea water from VFDs 210 and DC/DC converters 220, VFDs 210 and DC/DC converters 220 may be protected from corrosive and conductive sea water. Further, heating/cooling system 100 may be tested for integrity separately from keel cooler 300. In addition, while keel cooler 300 may include copper or brass components, in some embodiments, all components of heating/cooling system 100 may be formed from stainless steel, plastic, and/or aluminum, i.e., no copper or brass. In some embodiments, surge tank 180 may be fluidly connected to cooler 160 and pump supply manifold 150. Surge tank 180 may allow for fluid expansion of the first heat transfer fluid as the first heat transfer fluid temperature changes.

The foregoing outlines features of several embodiments so that a person of ordinary skill in the art may better understand the aspects of the present disclosure. Such features may be replaced by any one of numerous equivalent alternatives, only some of which are disclosed herein. One of ordinary skill in the art should appreciate that they may readily use the present disclosure as a basis for designing or modifying other processes and structures for carrying out the same purposes and/or achieving the same advantages of the embodiments introduced herein. One of ordinary skill in the art should also realize that such equivalent constructions do not depart from the spirit and scope of the present disclosure and that they may make various changes, substitutions, and alterations herein without departing from the spirit and scope of the present disclosure.

1. A marine vessel comprising:
a hull;
an electronics system positioned within the hull;
a heating/cooling system, the heating/cooling system positioned within the hull and the heating/cooling system including a first heat transfer fluid, the heating/cooling system comprising:
a pump;
a supply manifold, the supply manifold in fluid connection with the pump and the electronics system;
a return manifold, the return manifold in fluid connection with the electronics system; and
a cooler, the cooler in fluid connection with the return manifold and the pump, the cooler further including a second heat transfer fluid; and
a keel cooler, the keel cooler positioned outside the hull and in fluid connection with the cooler, the keel cooler including seawater and the second heat transfer fluid.

2. The marine vessel of claim 1 further comprising:
a thermostat, the thermostat positioned between the return manifold and the cooler; and
a pump supply manifold, the pump supply manifold positioned between the thermostat and the pump.

3. The marine vessel of claim 2, wherein the thermostat has a predetermined temperature setting.

4. The marine vessel of claim 3, wherein the thermostat is adapted to switch between the pump supply manifold when a temperature of the first heat transfer fluid is equal or below a predetermined temperature and the cooler when the temperature of the first heat transfer fluid is above a predetermined temperature.

5. The marine vessel of claim 3 further comprising a surge tank, the surge tank positioned between the cooler and the pump supply manifold.

6. The marine vessel of claim 5 further comprising a heater, the heater in fluid connection with the pump supply manifold.

7. The marine vessel of claim 6, wherein the pump, supply manifold, return manifold, thermostat, cooler, surge tank, heater, and pump supply manifold do not include copper or brass.

8. The marine vessel of claim 6, wherein the pump, supply manifold, return manifold, thermostat, cooler, surge tank, heater, and pump supply manifold are composed of stainless steel, plastic, or aluminum.

9. The marine vessel of claim 6, wherein the electronics system includes a VFD or a DC/DC converter.

10. The marine vessel of claim 1 wherein the first heat transfer fluid is non-reactive and non-conductive.

11. The marine vessel of claim 1, wherein two heating/cooling systems are present.

12. The marine vessel of claim 1, wherein the heating/cooling system is a closed system.

13. The marine vessel of claim 1, wherein the cooler is a plate and frame heat exchanger.

14. The marine vessel of claim 1, wherein the keel cooler includes copper or brass.
